(19) United States
(12) Patent Application Publication
(10) Pub. No.: US 2025/0037997 A1
(43) Pub. Date: Jan. 30, 2025

(54) EPITAXIAL GROWTH OF STRAINED Si/SiGe SUPERLATTICE

(71) Applicant: Applied Materials, Inc., Santa Clara, CA (US)

(72) Inventors: Ruiying HAO, San Jose, CA (US); Thomas John KIRSCHENHEITER, New York, NY (US); Fredrick FISHBURN, Los Gatos, CA (US); Abhishek DUBE, Fremont, CA (US); Raghuveer S. MAKALA, Campbell, CA (US); Balasubramanian PRANATHARTHIHARAN, San Jose, CA (US)

(73) Assignee: Applied Materials, Inc., Santa Clara, CA (US)

(21) Appl. No.: 18/781,631

(22) Filed: Jul. 23, 2024

Related U.S. Application Data
(60) Provisional application No. 63/528,533, filed on Jul. 24, 2023.

(51) Int. Cl. H01L 21/02; H01L 21/306

(52) U.S. Cl. CPC H01L 21/02532; H01L 21/02529; H01L 21/30604

(57) ABSTRACT

A semiconductor device and a method for manufacturing thereof. A substrate is provided. One or more groups of layers are formed on top of the substrate. A compensation layer is formed on top of at least one group of layers. At least one silicon layer is formed on top of the compensation layer. At least a portion of one or more layers in the one or more groups of layers is etched. The semiconductor device is formed.

### CROSS-REFERENCE TO RELATED APPLICATIONS

The present application claims priority to U.S. Provisional Patent No. 63/528,533 to Hao et al., filed Jul. 24, 2023, and entitled “Epitaxial Growth of Strained Si/SiGe Superlattice,” and incorporates its disclosure herein by reference in its entirety.

### TECHNICAL FIELD

This disclosure relates generally to semiconductor devices, and in particular, semiconductor devices that employ epitaxially-grown structures and associated processes that are capable of reducing strain that may be induced by a mismatch in lattice elements.

### BACKGROUND

Epitaxial layer growth may refer to a crystal growth and/or deposition of material, whereby new crystalline layers may be formed using predetermined orientations vis-à-vis crystalline seed layer with the deposited film being referred to as an epitaxial layer. Orientations of epitaxial and seed layers may be determined using each material's crystal lattice's orientation. Epitaxial growth processes are used in manufacturing of semiconductors, with semiconductor films being epitaxially grown on substrates. Heteroepitaxial growth involves epitaxial growth of materials that are different from one another. However, during such epitaxial growth processes (e.g., using Si/SiGe films), a strain may be introduced from a mismatch in lattice elements of Si lattice and Ge lattice. The mismatch may be produced as a result of lattice elements having different lattice constants. For example, the lattice constant for Si is 5.431 A and for Ge is 5.658 A. This lattice constant mismatch can cause compressive stress and wafer bow, which can increase with the number of Ge layers in the stack. Further, the stress can induce epitaxial defects generated in the films, thus requiring bow compensation.

### SUMMARY

In some implementations, the current subject matter relates to a method for manufacturing a semiconductor device. The method may include providing a substrate, forming one or more groups of layers on top of the substrate, forming a compensation layer on top of at least one group of layers, forming at least one silicon layer on top of the compensation layer, etching at least a portion of one or more layers in the one or more groups of layers, and forming the semiconductor device.

In some implementations, the current subject matter includes one or more of the following optional features. One or more groups of layers may include one or more silicon-germanium layers. At least one silicon-germanium layer in one or more silicon-germanium layers may have a higher concentration of germanium than at least another silicon-germanium layer in one or more silicon-germanium layers. At least one silicon-germanium layer may have a concentration of germanium of at least approximately 15% to at least approximately 25%. At least another silicon-germanium layer may have a concentration of germanium of approximately 0-25%.

In some implementations, etching may include etching the at least one silicon-germanium layer. Etching may further include etching the at least another silicon-germanium layer subsequent to etching the at least one silicon-germanium layer.

In some implementations, etching may include etching all layers in the one or more groups of layers.

In some implementations, the compensation layer may be a silicon-based layer. The silicon-based layer may include at least one of the following: a silicon-carbon layer, a silicon-boron layer, a silicon-carbon-boron layer, and any combinations thereof.

In some implementations, the method may also include stacking a plurality of the groups of layers prior to the forming of the compensation layer. At least one formed silicon layer may be a working silicon layer channel of the semiconductor device. At least one formed silicon layer may be a non-working silicon layer of the semiconductor device. The non-working silicon layer may be formed adjacent to the compensation layer.

In some implementations, the semiconductor device may include a plurality of silicon layers and a plurality of compensation layers. Each compensation layer in the plurality of compensation layers may be arranged every predetermined number of silicon layers in the plurality of silicon layers.

In some implementations, the current subject matter relates to a semiconductor device. The device may include a substrate, at least one compensation layer, and at least one silicon layer formed on top of the compensation layer. One or more groups of layers may be formed on top of the substrate and at least one compensation layer may be formed on top of at least one group of layers in the one or more groups of layers, where at least a portion of one or more layers in one or more groups of layers may be etched away. In some implementations, the current subject matter's semiconductor device may include one or more of the above discussed optional features.

The details of one or more variations of the subject matter described herein are set forth in the accompanying drawings and the description below. Other features and advantages of the subject matter described herein will be apparent from the description and drawings, and from the claims.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. The drawings are schematic in nature and do not represent actual dimensions or aspect ratios. In the drawings,

FIGS. 1a-c illustrate example semiconductor devices, according to some implementations of the current subject matter;

FIG. 2 illustrates an example process for manufacturing a semiconductor device, according to some implementations of the current subject matter; and

FIG. 3 illustrates another example process for manufacturing a semiconductor device, according to some implementations of the current subject matter.

### DETAILED DESCRIPTION

To address these and potentially other deficiencies of currently available solutions, one or more implementations of the current subject matter relate to methods, systems, articles of manufacture, and the like that can, among other possible advantages, provide semiconductor devices that use heteroepitaxial structures and associated processes that may be capable of reducing strain that may be induced by a mismatch in one or more lattice elements.

In some implementations, the current subject matter relates to an ability to compensate and/or reduce wafer bow in semiconductor devices that have been epitaxially grown, such as, for the purposes of producing a dynamic random-access memory (DRAM) device. A typical DRAM device may include alternating layers of silicon (Si) and silicon-germanium (SiGe) that may be epitaxially grown from a crystal silicon substrate. A mismatch may occur in the lattice between Si and Ge, which may cause a strain causing wafer bow. In thin layers, such wafer bow is less problematic than in thick layers. To solve this issue, the current subject matter's compensation and/or reduction may be performed either during one or more the stages of the heteroepitaxial growth process and/or after completion of one or more stages and/or the entire growth process. The compensation may be performed through one or more of the following ways: use of different concentrations of silicon-germanium layers, addition of a compensation layer (e.g., silicon-carbide (SiC), silicon-boron (SiB), and/or silicon-carbide-boron (SiCB), and/or other types of compensation layers) after certain number of layers in the stack, as well as use of different etching processes to etch away silicon-germanium layers.

It should be noted that, when used herein, a substrate may refer to any substrate and/or material surface formed on a substrate upon which film processing may be performed during a fabrication process. A substrate material may, for example, include, but is not limited to, silicon, silicon oxide, strained silicon, silicon on insulator (SOI), carbon doped silicon oxides, amorphous silicon, doped silicon, germanium, gallium arsenide, glass, sapphire, and/or any other materials, such as, for instance, metals, metal nitrides, metal alloys, and/or any other conductive materials, etc. (which may be specific to a particular implementation, application, use, etc.) Substrates may also include semiconductor wafers. Substrates may be exposed to one or more pretreatment processes, such as, for example, to polish, etch, reduce, oxidize, hydroxylate, anneal, UV cure, e-beam cure and/or bake the substrate surface. The substrate surface and/or substrate may include an underlayer, such as, for instance, upon depositing a film/layer and/or partial film/layer onto a substrate surface, an exposed surface of the deposited film/layer becomes the substrate surface.

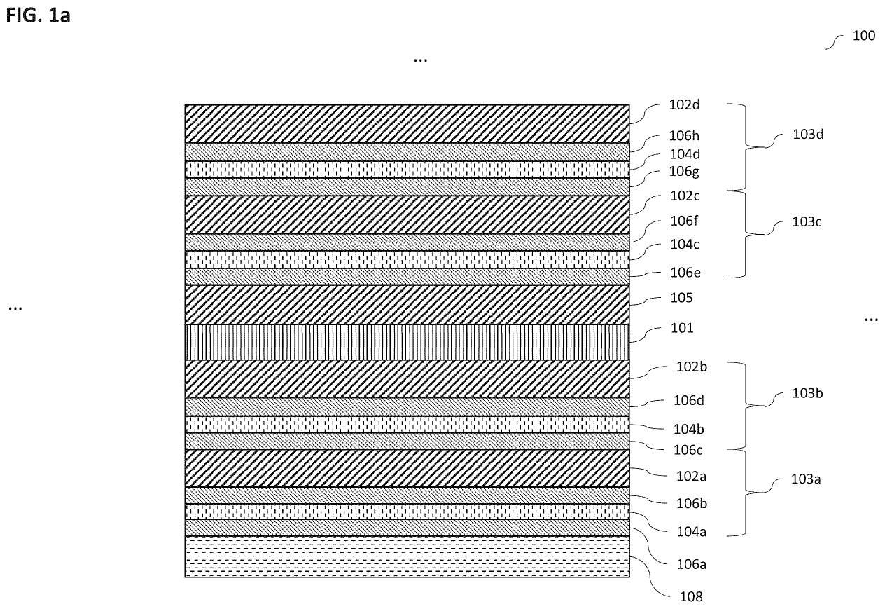

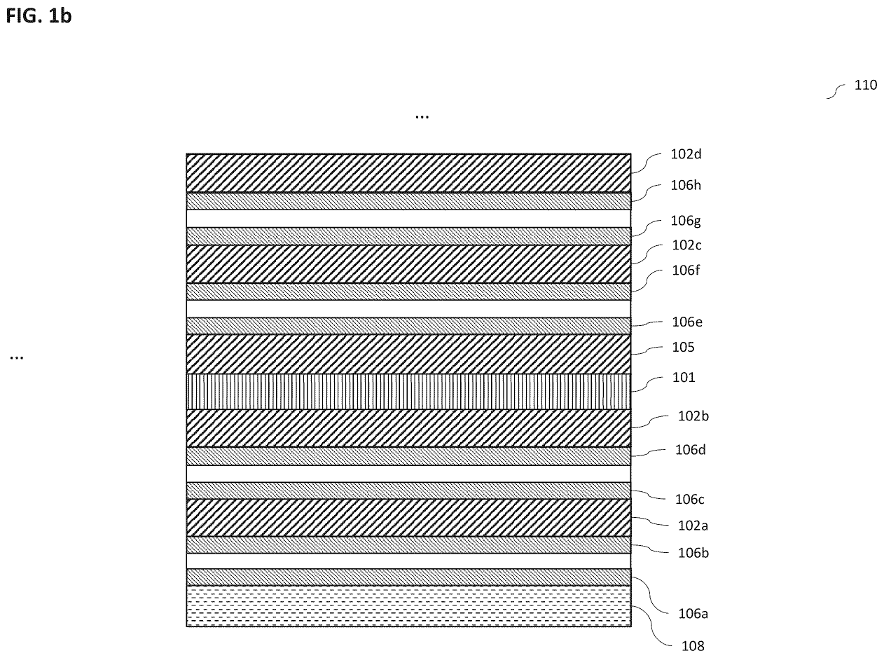

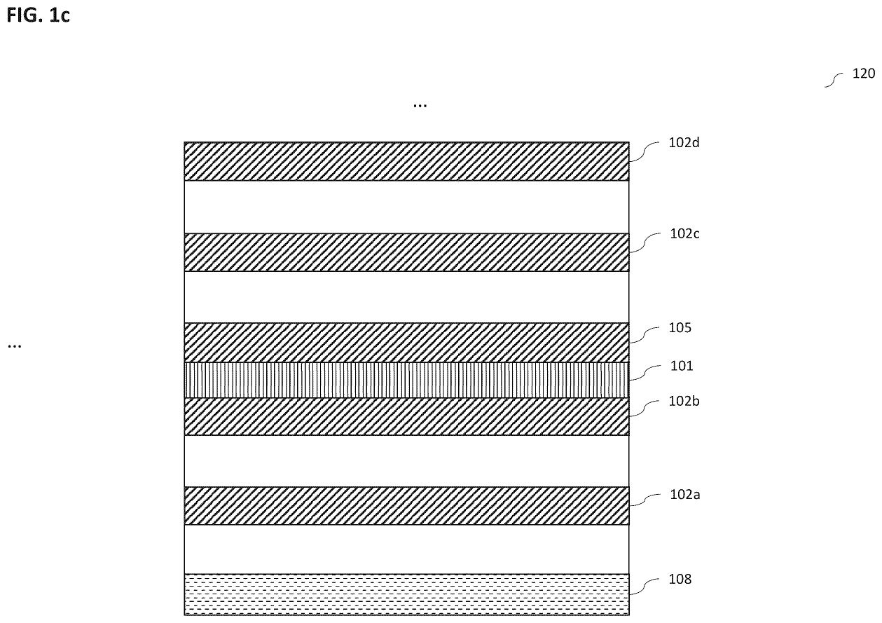

FIGS. 1a-c illustrate example semiconductor devices 100-120, respectively, according to some implementations of the current subject matter. The devices 100-120 may represent devices at different stages of formation of dynamic random-access memory (DRAM) devices, and/or any other type of memory devices. The devices 100-120 may be configured to include a plurality of stacked layers and/or groups of layers that may be disposed directly on top of one another and/or side-by-side. For ease of illustration, FIGS. 1a-c show only a limited number of such layers. As can be understood, any number of layers may be stacked directly on top of one another. As used herein, the term “on”, as used with respect to a film and/or a layer of a film, may include the film and/or layer being directly disposed on a surface, and/or on one or more underlayers between the film and/or layer and the surface.

A layer may refer to a single crystalline layer of material and/or multiple crystalline layers of the same material, which, may, upon being combined, form a single crystalline layer. The devices 100-120 may, for example, include a plurality of alternating silicon (Si) and silicon germanium (SiGe) layers, and/or compensation layers (e.g., SiC, SiB, SiCB), where layers may be arranged in a predetermined order, and where thicknesses and/or heights of each Si, SiGe layer may vary. Alternatively, or in addition, at least one of Si, SiGe, and/or compensation layers may have thicknesses and/or heights that may be same and/or different less than thicknesses and/or heights of at least another one of Si, SiGe, and/or compensation layers. As can be understood, any combination of numbers, groups and/or thicknesses/heights of layers is possible.

In some example, non-limiting implementations, one or more Si, SiGe and/or compensation layers of devices 100-120 may be doped with and/or include at least one dopant. Some non-limiting examples of dopants may include carbon, boron, phosphorous, oxygen, nitrogen, and/or any other types of dopants, and/or any combinations thereof. Moreover, the devices 100-120 may be configured to include any combination of doped and non-doped Si, SiGe, and/or compensation layers. For example, a doped Si layer may be disposed adjacent and/or at each side of a doped and/or non-doped SiGe layer. Alternatively, or in addition, a doped SiGe layer may be disposed adjacent and/or at each side of a doped and/or non-doped Si layer. Each doped and/or non-doped layer may have a respective thickness and/or height that may be selected in accordance with design requirements and/or characteristics for the devices 100-120. Further, each doped layer may have specific desired doping concentrations (for instance, of one or more dopants), which may again be selected in accordance with particular requirements/characteristics of the devices 100-120. The doping concentration may be configured to be uniform throughout the entire stack of layers. Alternatively, or in addition, the doping concentration may be non-uniform and may vary from doped layer to doped layer in the stack, e.g., the doping concentration may vary from a bottom doped layer in the stack to the top layer in the stack (if so desired). Such non-uniform doping may assist in formation of uniform recess of SiGe layers (depending on recess etch conditions).

Further, in some implementations, one or more layers of the devices 100-120 may have a different concentration of specific lattice elements and/or combination of lattice elements than at least another layer in the stack. The devices 100-120 may include one or more groups of adjacent layers (e.g., one layer being positioned on top of another layer) with different concentrations.

Referring to FIG. 1a, the device 100 may include silicon layers 102 (a, b, c, d), one or more first silicon-germanium layers 104 (a, b, c, d) having a first of silicon-germanium (SiGe), one or more second silicon-germanium layers 106 (a, b, c, d, e, f, g, h), a substrate 108, and a wafer bow compensation layer (or “compensation layer” as used herein) 101. As stated above, any number of silicon layers 102, first and second silicon germanium layers 104 and 106, and compensation layers 101. For ease of illustration a single compensation layer 101 is shown in FIG. 1a. The substrate 108 may be a silicon wafer substrate. As can be understood, any other type of material may be used for the substrate 108. The compensation layer 101 may be a silicon-carbide (SiC) layer, a silicon-boron (SiB) layer, a silicon-carbide-boron (SiCB) layer, and/or any other type of layer. The compensation layer 101 may be used to partially and/or entirely compensate the compressive stress that may be induced by the combination of Si and SiGe layers below it. As such, more than one compensation layer may be implemented in the layer stack.

In some implementations, the first SiGe layers 104 may have one or first concentration of germanium, while the second SiGe layers 106 may have another or second concentration of germanium. The concentration of germanium in the SiGe layers 104 may be less than concentration of germanium in the SiGe layers 106. For example, the layers 104 may have a 0-25% concentration of germanium (e.g., 0-15% concentration of germanium; 5% concentration of germanium) and layers 106 may have approximately 15% concentration of germanium to approximately 25% concentration of germanium (e.g., 15% concentration of germanium). The concentration of germanium in one layer 104 may be same or different from at least another layer 104 (e.g., concentrations of germanium in each layer 104 in the stack may be the same; concentration of germanium in layer 104a may be different than concentration of germanium in layer 104b). Similarly, the concentration of germanium in one layer 106 may be the same or different from at least another layer 106 (e.g., all layers 106 may have the same concentration of germanium; layer 106a may have a different concentration of germanium than layer 106b; etc.).

The silicon layers 102 may serve as channels for the 3D DRAM. The SiGe layers 106 may serve as sacrificial layers that may be etched away. The SiGe layers 104, due to their lower concentrations of germanium may serve as buffer layers, thus, may be used to minimize impact of lattice constant mismatch between layers.

In some implementations, the silicon layers 102 and the first and second SiGe layers 104, 106 may be arranged in groups 103 (a, b, c, d). For example, group 103a may include a SiGe layer 106a having a first concentration of germanium, a SiGe layer 104a having a second concentration of germanium, a SiGe layer 106b having a first concentration of germanium, and a silicon layer 102a. Alternatively, or in addition, the SiGe layer 106b may have a concentration of germanium that may be different from the concentration of germanium in the SiGe layer 106a. Similarly, group 103b may include a SiGe layer 106c having a first concentration of germanium, a SiGe layer 104b having a second concentration of germanium, a SiGe layer 106d having a first (or different concentration of germanium than in layer 106c), and a silicon layer 102b. Group 103c may include a SiGe layer 106e having a first concentration of germanium, a SiGe layer 104c having a second concentration of germanium, a SiGe layer 106f having a first (or different concentration of germanium than in layer 106e), and a silicon layer 102c. Group 103d may include a SiGe layer 106g having a first concentration of germanium, a SiGe layer 104d having a second concentration of germanium, a SiGe layer 106h having a first (or different concentration of germanium than in layer 106g), and a silicon layer 102d. As stated above, the concentration of germanium in the SiGe layers 106 may be between approximately 0-25% and the concentration of germanium in the SiGe layers 104 may be approximately 15%-25%, i.e., higher than the concentration of germanium in one or more or each of the SiGe layers 106.

Further, in group 103a, the layers may be arranged in the following example configuration: the layer 104a may be disposed on top of the layer 106a, the layer 106b may be disposed on top of the layer 104a, and the layer 102a may be disposed on top of the layer 106b. The layer 106a may be disposed on top of the substrate 108.

In group 103b, the layer 106c may be disposed on top of the layer 102a, the layer 104b may be disposed on top of the layer 106c, the layer 106d may be disposed on top of the layer 104b, and the layer 102b may be disposed on top of the layer 106d. Moreover, the layer 102b may be disposed below the compensation layer 101. A silicon layer 105 may be disposed on top of the compensation layer 101, thus, sandwiching the compensation layer between the silicon layers 102b and 105. In some implementations, the combination of the layers sandwiching the compensation layer (e.g., layers 102b-101-105) may be deemed as not an active part of the eventually formed semiconductor device. The compensation layer 101 and/or the sandwiched combination of layers (e.g., 102b-101-105) may be used to reduce wafer bow and/or stress that may be resulting from the lattice constant mismatch.

In group 103c, the layer 106e may be disposed on top of the layer 105, the layer 104c may be disposed on top of the layer 106e, the layer 106f may be disposed on top of the layer 104c, and the layer 102c may be disposed on top of the layer 106f. The group 103c may be similar to the group 103a and/or 103b. For example, concentrations of germanium of one or more of the layers may be similar and/or different from the concentration of germanium in similarly disposed layers in the other groups.

In group 103d, the layer 106g may be disposed on top of the layer 102c, the layer 104d may be disposed on top of the layer 106g, the layer 106h may be disposed on top of the layer 104d, and the layer 102d may be disposed on top of the layer 106h. In some implementations, depending on a desired configuration of the semiconductor device, another group 103 of the above layers 102, 104, and 106 may be disposed on top of group 103d. Alternatively, or in addition, another compensation layer (e.g., similar to layer 101) may be disposed on top of group 103d. If another compensation layer is disposed on top of group 103d, such compensation layer may be followed by a silicon layer (e.g., similar to silicon layer 105 being disposed on top of compensation layer 101).

As can be understood, any arrangement and/or number of groups 103 and/or compensation layers 101 with additional silicon layers 105 may be used. For example, a compensation layer may be disposed after a certain number of pairs of groups 103, thereby creating a periodic arrangement of compensation layers within the stack. Alternatively, or in addition, the compensation layers may be arranged non-periodically, for example, one compensation layer may be disposed after x number of groups 103, another compensation layer may be subsequently arranged after y number of groups 103, and yet another compensation layer may be subsequently arranged after z number of groups 103, where x≠y≠z.

As shown in FIG. 1a, the thicknesses and/or heights of the silicon layers 102 and the layer 105 may be uniform throughout the device. Alternatively, or in addition, such thicknesses/heights may vary from one layer to another. Further, thicknesses/heights of silicon layers 102, 105 may be greater than thicknesses/heights of silicon germanium layers 104 and/or 106. Alternatively, or in addition, thickness/height of at least one silicon germanium layer 104 may be greater than thickness/height at least one silicon germanium layer 102. Further, while FIG. 1a, illustrates uniform thickness/height for each silicon layer 102 (and/or layer 105) and similarly, for each silicon germanium layers 104 and/or 106, it may be understood that the thicknesses/heights of such respective layers 102, 104, 106 might not be uniform. Disposition or growth of each respective layer 102, 105, 104, 106 may be performed in accordance with any existing techniques.

In some implementations, the compensation layer 101 may include uniform and/or varying concentrations of carbon (C), boron (B), and/or carbon-boron (CB), and/or any other elements. Alternatively, or in addition, the concentration of these added elements and/or groups of elements (e.g., C, B, CB) may vary throughout the compensation layer 101. Further, the concentrations of the added elements/groups of elements may vary from one compensation layer 101 to another compensation layer 101. As can be understood, concentration of each layer in the stack may be selected in accordance with the specification of the semiconductor device, tolerance for a particular wafer bow, and/or any other factors.

FIG. 1b illustrates an example device 110 that may be formed as a result of etching of one or more higher germanium concentration layers 104. As shown in FIG. 1b, the device 110 may include silicon layers 102 (a, b, c, d), one or more second silicon-germanium layers 106 (a, b, c, d, e, f, g, h), substrate 108, and compensation layer 101. The layers 104 (a, b, c, d) have been etched away. Etching away of layers 104 may be performed with partial selectivity with respect to the layers having lower germanium concentration, i.e., layers 106.

While FIG. 1b shows that all layers 104 have been etched away, in some example implementations, one or more layers 104 may be selected for etching away, while other layers are not etched away. For example, layer 104a may be etched away, while layer 104c is not. Selection of specific layers 104 for etching away may be performed in accordance with a desired specification of the semiconductor device. Further, etching of layers 104 may involve etching of only one or more portions of one or more layers 104. For example, a portion of the layer 104b may be etched away, while the layer 104a remains intact. As can be understood, the layers 104 and/or any portions thereof may be etched in any desired configuration. Determination of the etching configurations may be based on a particular configuration of the final semiconductor device, a specific tolerance for a wafer bow, and/or any other factors.

In some example implementations, one or more layers 106, i.e., layers having lower germanium concentration that layers 104, may also be etched. Etching may be partial and/or full (e.g., as shown in FIG. 1c). As shown in FIG. 1c, the device 120 (that may be formed after etching away layers 106 from device 110 shown in FIG. 1b) may include silicon layers 102 (a, b, c, d), the substrate 108, and the compensation layer 101. The layers 106 have been etched away. Along with etching layers 106 away, portions of one or more of the silicon layers 102 may also be etched away. Moreover, the etching method for etching layers 106 may be different from the etching method that was used to etch layers 104.

Similar to the etching that resulted in device 110 shown in FIG. 1c, one or more layers 106 may be selected for etching away, while other layers remain intact. The selection of layers 106 for etching may be performed randomly, on a group-by-group basis, and/or in any other fashion. For example, within group 103a, layer 106a may be etched away, while layer 106b is not. Further, in group 103b, both layers 106c and 106d may be etched away. Selection of specific layers 106 for etching away may be based on the specifics of the final semiconductor device. As discussed above with regard to layers 104, etching of layers 106 may include etching of only one or more of their portions. For instance, a portion of the layer 106e may be etched away, while the layer 106f may remain unetched. As can be understood, the layers 106 and/or any portions thereof may be etched in any desired order and/or configuration. Again, determination of the etching configurations may be based on a particular configuration of the final semiconductor device, a specific tolerance for a wafer bow, and/or any other factors.

As discussed above, the layer 101 may remain in the final structure of the semiconductor device and may be used to partially and/or fully compensate stress caused from the lattice mismatch between silicon and germanium. In some implementations, the lattice constant of the layer 101 may be smaller than the lattice constant of the silicon layers 102b and 105 that sandwich it. The layer 101 may be a silicon-based layer and may be doped with a p-type dopant and/or include one or more doped regions that may be doped with such dopant. The p-type dopant may include, but is not limited to, carbon, boron, carbon and boron, and/or any other p-type dopant, and/or any combination thereof. Throughout the structure of the semiconductor device, there may be several layers 101 that may be similar to one another and/or different. For example, one layer 101 may be a silicon carbon layer, while another layer 101 may be a silicon-boron layer. The layers 101 (along with subsequent layer 105) may be disposed after any number of groups 103. For example, layers 101 may be disposed every two groups 103 and/or randomly. The layers 101 may be used to support the final semiconductor device and, along with silicon layers adjacent to them (e.g., layers 102b and 105) do not serve as active components of the semiconductor device.

In some implementations, thickness, height, number, and/or concentration of each layer 101, 102, 104, 105, 106, and 108 may be determined in accordance with specific characteristics of the final semiconductor device, one or more indented uses and/or particular applications of the device. For example, thickness and/or height of all layers 104 may be uniform throughout the device. Alternatively, or in addition, each layer 104 may have its own thickness and/or height. Similar configurations may be applicable to all other layers.

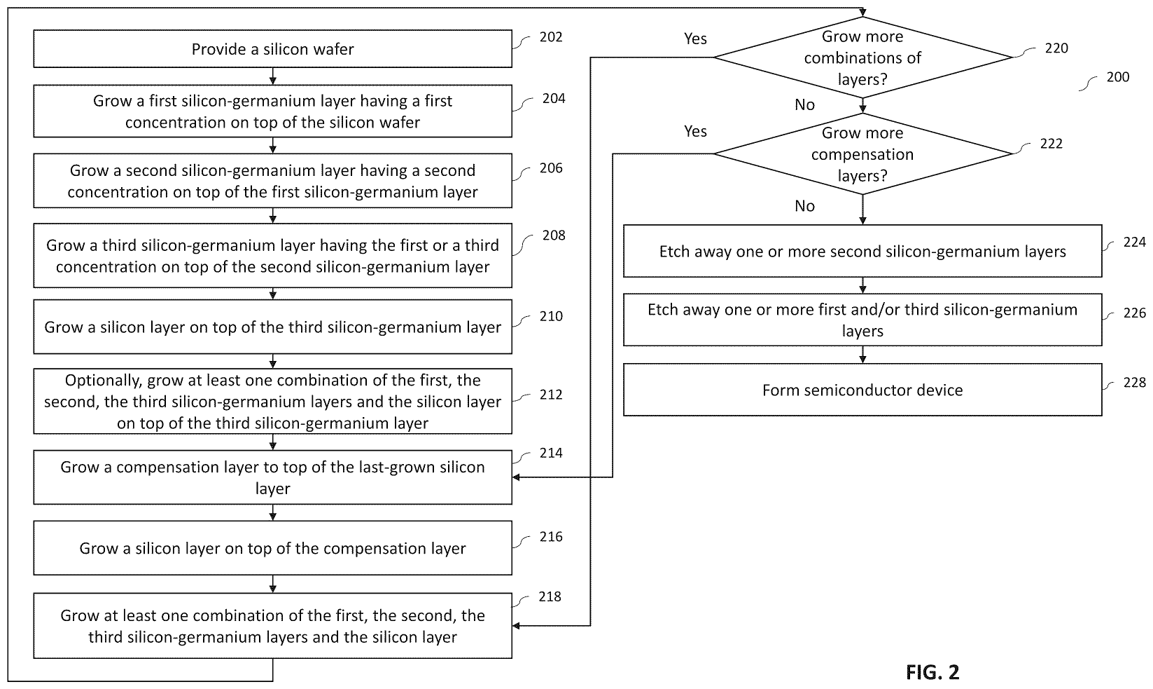

FIG. 2 illustrates an example process 200 for manufacturing a semiconductor device, according to some implementations of the current subject matter. The process 200 may be used to manufacture one or more devices shown in FIGS. 1a-c. The process 200 may begin, at 202, with a silicon wafer or substrate, such as for example, substrate 108 as shown in FIGS. 1a-c. A first silicon-germanium layer (e.g., layer 106a and/or one or more layers 106) may be grown on top of the silicon wafer, at 204. The first silicon-germanium layer may have a first concentration of germanium (e.g., between 0-25%).

At 206, a second silicon-germanium layer (e.g., layer 104a and/or one or more layers 104) may be grown on top of the first silicon-germanium layer, at 206. The second silicon-germanium layer may have a second concentration of germanium (e.g., approximately 15% to approximately 25%), which may be higher than the first concentration of germanium in the first silicon-germanium layer.

A third silicon-germanium layer (e.g., layer 106b and/or one or more layers 106) may be grown on top of the second silicon-germanium layer, at 208. The third silicon-germanium layer may have a third concentration of germanium (e.g., between 0-25%). The third concentration of germanium may be similar than the first concentration of germanium in the first silicon layer. It may also be less than the second concentration of germanium in the second silicon-germanium layer.

At 210, a silicon layer (e.g., silicon layer 102a and/or any other layers 102) may be grown on top of the third silicon-germanium layer. This silicon layer may be similar to the substrate layer 108 and/or any other silicon layers in the device. The grown silicon layer may serve as a working channel in the semiconductor device.

The above growth process, as represented by operations 204-210, may be optionally repeated, at 212, to grow one or more groups (e.g., groups 103) of first, second, third silicon germanium layers (e.g., layers 104, 106) and a silicon layer (e.g., layer 102). Any number of groups may be grown. This may depend on a particular specification of the semiconductor device. Further, the grown layers in each group may have their own thicknesses/heights, and/or concentrations of elements.

At 214, a compensation layer (e.g., layer 101) may be grown on top of the last-grown silicon layer (e.g., layer 102b, as shown in FIGS. 1a-c). The compensation layer may include a silicon-carbon layer, a silicon-boron layer, a silicon-carbon-boron layer, and/or any other silicon-based layer, and/or any combinations thereof. The compensation layer may serve as a structural support for the semiconductor device.

The compensation layer may be followed by a silicon layer (e.g., layer 105) grown on top of it, at 216. In some implementations, the combination of silicon layers (e.g., layer 102b and layer 105) sandwiching the compensation layer (e.g., layer 101) might not be used as an active working channel in the semiconductor device and instead, may be used for reduction of wafer bow and/or structural support.

At 218, one or more groups of first, second, third silicon germanium layers and a silicon layer may be grown. At 220, a determination may be made whether or not to grow more groups of such layers. If so, the process 200 may return to 218 for further growth of first, second, third silicon germanium layers and a silicon layer. Otherwise, the process 200 may proceed to determine whether to grow more compensation layers (e.g., layers 101), at 222. If so, the process may return to 214, where additional compensation layers may be grown. This process may be repeated as many time as desired.

If no further compensation and/or groups of layers are desired, one or more second silicon-germanium layers may be etched away, at 224. The etching may involve etching entire second silicon-germanium layers, etching portions of such second silicon-germanium layers, selecting one or more second silicon-germanium layers for full and/or partial etching, and/or any combination thereof.

At 226, one or more first and/or third silicon-germanium layers may be etched away. Similarly, the etching may involve etching entire first and/or third silicon-germanium layers, etching portions of first and/or third silicon-germanium layers, selecting one or more first and/or third silicon-germanium layers for full and/or partial etching, and/or any combination thereof. Once etching is complete, the semiconductor device may be formed, at 228. This process may involve further etching, polishing, and/or any other operations.

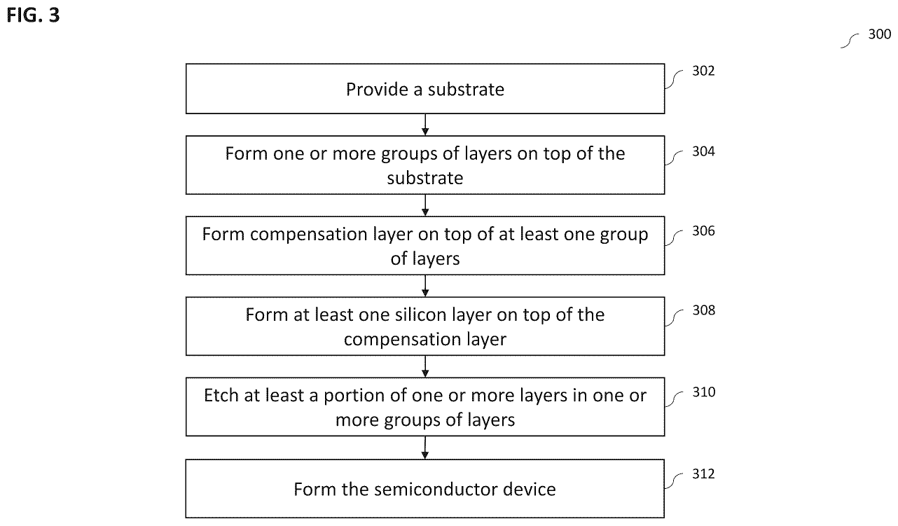

FIG. 3 illustrates an example process 300 for manufacturing a semiconductor device, according to some implementations of the current subject matter. The process 300 may include any of the components and/or operations discussed herein with regard to FIGS. 1a-2. At 302, a substrate may be provided (e.g., substrate or silicon wafer 108). At 304, one or more groups of layers may be formed on top of the substrate. The groups of layers may include one or more silicon-germanium layers having varying concentration of germanium. At 306, a compensation layer may be formed on top of at least one group of layers. The compensation layer may be a silicon-based layers, such as, for example, a silicon-carbon layer, a silicon-boron layer, a silicon-carbon-boron layer, and/or any other silicon-based layer, and/or any combinations thereof.

At 308, at least one silicon layer may be formed on top of the compensation layer. At 310, at least a portion of one or more layers in one or more groups of layers may be etched away. At 312, the semiconductor device having one or more of the above layers may be formed.

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in implementations.

Some implementations may be described using the expression “one implementation” or “an implementation” along with their derivatives. These terms mean that a particular feature, structure, or characteristic described in connection with the implementation is included in at least one implementation. The appearances of the phrase “in one implementation” in various places in the specification are not necessarily all referring to the same implementation. Moreover, unless otherwise noted the features described above are recognized to be usable together in any combination. Thus, any features discussed separately may be employed in combination with each other unless it is noted that the features are incompatible with each other.

In aspect, a method for manufacturing a semiconductor device may include providing a substrate, forming one or more groups of layers on top of the substrate, forming a compensation layer on top of at least one group of layers, forming at least one silicon layer on top of the compensation layer, etching at least a portion of one or more layers in the one or more groups of layers, and forming the semiconductor device.

The method may also include wherein the one or more groups of layers include one or more silicon-germanium layers.

The method may also include wherein at least one silicon-germanium layer in the one or more silicon-germanium layers has a higher concentration of germanium than at least another silicon-germanium layer in the one or more silicon-germanium layers.

The method may also include wherein the at least one silicon-germanium layer has a concentration of germanium of approximately 15% to approximately 25%.

The method may also include wherein the at least another silicon-germanium layer has a concentration of germanium of approximately 0-25%.

The method may also include wherein the etching includes etching the at least one silicon-germanium layer.

The method may also include wherein the etching includes etching the at least another silicon-germanium layer subsequent to etching the at least one silicon-germanium layer.

The method may also include wherein the etching includes etching all layers in the one or more groups of layers.

The method may also include wherein the compensation layer is a silicon-based layer.

The method may also include wherein the silicon-based layer includes at least one of the following: a silicon-carbon layer, a silicon-boron layer, a silicon-carbon-boron layer, and any combinations thereof.

The method may also include stacking a plurality of the groups of layers prior to the forming of the compensation layer.

The method may also include wherein at least one formed silicon layer is a working silicon layer channel of the semiconductor device.

The method may also include wherein at least one formed silicon layer is a non-working silicon layer of the semiconductor device.

The method may also include wherein the non-working silicon layer is formed adjacent to the compensation layer.

The method may also include wherein the semiconductor device includes a plurality of silicon layers and a plurality of compensation layers.

The method may also include wherein each compensation layer in the plurality of compensation layers is arranged every predetermined number of silicon layers in the plurality of silicon layers.

In one aspect, a semiconductor device may include a substrate, at least one compensation layer, and at least one silicon layer formed on top of the compensation layer, wherein one or more groups of layers are formed on top of the substrate and the at least one compensation layer is formed on top of at least one group of layers in the one or more groups of layers, wherein at least a portion of one or more layers in the one or more groups of layers is etched away.

The semiconductor device may also include wherein the one or more groups of layers include one or more silicon-germanium layers.

The semiconductor device may also include wherein at least one silicon-germanium layer in the one or more silicon-germanium layers has a higher concentration of germanium than at least another silicon-germanium layer in the one or more silicon-germanium layers.

The semiconductor device may also include wherein the at least one silicon-germanium layer has a concentration of germanium of approximately 15% to approximately 25%.

The semiconductor device may also include wherein the at least another silicon-germanium layer has a concentration of germanium of approximately 0-25%.

The semiconductor device may also include wherein the at least one silicon-germanium layer is etched away.

The semiconductor device may also include wherein the at least another silicon-germanium layer is etched away subsequent to etching of the at least one silicon-germanium layer.

The semiconductor device may also include wherein all layers in the one or more groups of layers are etched away.

The semiconductor device may also include wherein the compensation layer is a silicon-based layer.

The semiconductor device may also include wherein the silicon-based layer includes at least one of the following: a silicon-carbon layer, a silicon-boron layer, a silicon-carbon-boron layer, and any combinations thereof.

The semiconductor device may also include a plurality of the groups of layers, where the plurality of the groups of layers is stacked prior to forming of the compensation layer.

The semiconductor device may also include wherein at least one formed silicon layer is a working silicon layer channel of the semiconductor device.

The semiconductor device may also include wherein at least one formed silicon layer is a non-working silicon layer of the semiconductor device.

The semiconductor device may also include wherein the non-working silicon layer is formed adjacent to the compensation layer.

The semiconductor device may also include a plurality of silicon layers and a plurality of compensation layers.

The semiconductor device may also include wherein each compensation layer in the plurality of compensation layers is arranged every predetermined number of silicon layers in the plurality of silicon layers.

It is emphasized that the abstract of the disclosure is provided to allow a reader to quickly ascertain the nature of the technical disclosure. It is submitted with the understanding that it will not be used to interpret or limit the scope or meaning of the claims. In addition, in the foregoing detailed description, it can be seen that various features are grouped together in a single implementation for the purpose of streamlining the disclosure. This method of disclosure is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the detailed description, with each claim standing on its own as a separate implementation. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims.

The foregoing description of example implementations has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner and may generally include any set of one or more limitations as variously disclosed or otherwise demonstrated herein.

What is claimed:

1. A method for manufacturing a semiconductor device, comprising:
providing a substrate;
forming one or more groups of layers on top of the substrate;
forming a compensation layer on top of at least one group of layers;
forming at least one silicon layer on top of the compensation layer;
etching at least a portion of one or more layers in the one or more groups of layers; and
forming the semiconductor device.

2. The method according to claim 1, wherein the one or more groups of layers include one or more silicon-germanium layers.

3. The method according to claim 2, wherein at least one silicon-germanium layer in the one or more silicon-germanium layers has a higher concentration of germanium than at least another silicon-germanium layer in the one or more silicon-germanium layers.

4. The method according to claim 3, wherein the at least one silicon-germanium layer has a concentration of germanium of approximately 15% to approximately 25%.

5. The method according to claim 4, wherein the at least another silicon-germanium layer has a concentration of germanium of approximately 0-25%.

6. The method according to claim 3, wherein the etching includes etching the at least one silicon-germanium layer.

7. The method according to claim 6, wherein the etching includes etching the at least another silicon-germanium layer subsequent to etching the at least one silicon-germanium layer.

8. The method according to claim 1, wherein the etching includes etching all layers in the one or more groups of layers.

9. The method according to claim 1, wherein the compensation layer is a silicon-based layer.

10. The method according to claim 9, wherein the silicon-based layer includes at least one of the following: a silicon-carbon layer, a silicon-boron layer, a silicon-carbon-boron layer, and any combinations thereof.

11. The method according to claim 1, further comprising stacking a plurality of the groups of layers prior to the forming of the compensation layer.

12. The method according to claim 1, wherein at least one formed silicon layer is a working silicon layer channel of the semiconductor device.

13. The method according to claim 1, wherein at least one formed silicon layer is a non-working silicon layer of the semiconductor device.

14. The method according to claim 13, wherein the non-working silicon layer is formed adjacent to the compensation layer.

15. The method according to claim 1, wherein the semiconductor device includes a plurality of silicon layers and a plurality of compensation layers.

16. The method according to claim 15, wherein each compensation layer in the plurality of compensation layers is arranged every predetermined number of silicon layers in the plurality of silicon layers.

17. A semiconductor device, comprising:
a substrate;
at least one compensation layer; and
at least one silicon layer formed on top of the compensation layer;
wherein one or more groups of layers are formed on top of the substrate and the at least one compensation layer is formed on top of at least one group of layers in the one or more groups of layers, wherein at least a portion of one or more layers in the one or more groups of layers is etched away.

18. The semiconductor device according to claim 17, wherein the one or more groups of layers include one or more silicon-germanium layers, wherein at least one silicon-germanium layer in the one or more silicon-germanium layers has a higher concentration of germanium than at least another silicon-germanium layer in the one or more silicon-germanium layers;
wherein the compensation layer is a silicon-based layer, the silicon-based layer includes at least one of the following: a silicon-carbon layer, a silicon-boron layer, a silicon-carbon-boron layer, and any combinations thereof.

19. The semiconductor device according to claim 17, further comprising a plurality of the groups of layers, where the plurality of the groups of layers is stacked prior to forming of the compensation layer.

20. The semiconductor device according to claim 17, wherein at least one formed silicon layer is at least one of: a working silicon layer channel of the semiconductor device and a non-working silicon layer of the semiconductor device, wherein the non-working silicon layer is formed adjacent to the compensation layer.
